(19) United States
(12) Patent Application Publication
(10) Pub. No.: US 2021/0288098 A1
(43) Pub. Date: Sep. 16, 2021

(54) SOLID-STATE IMAGING ELEMENT, METHOD FOR PRODUCING SOLID-STATE IMAGING ELEMENT, AND ELECTRONIC DEVICE

(71) Applicant: SONY SEMICONDUCTOR SOLUTIONS CORPORATION, KANAGAWA (JP)

(72) Inventor: SYOGO KUROGI, KUMAMOTO (JP)

(21) Appl. No.: 16/321,451

(22) PCT Filed: Jul. 14, 2017
(86) PCT No.: PCT/JP2017/025738

§ 371 Date: Jan. 28, 2019

(30) Foreign Application Priority Data
Aug. 18, 2016 (JP) 2016-160806

(51) Int. Cl. H01L 27/146

(52) U.S. Cl. CPC H01L 27/14636; H01L 27/14645; H01L 27/14621; H01L 27/14689; H01L 27/14629; H01L 27/1464; H01L 27/14685; H01L 27/14627

(57) ABSTRACT

To reduce the probability of lowering an image quality in a solid-state imaging element such as a rear surface irradiation type CMOS image sensor.

A solid-state imaging element including: a semiconductor substrate on which a plurality of pixels each including a photoelectric conversion section are disposed in parallel along a planar direction; and a wiring layer which is stacked on a surface on a side opposite to a light incidence surface of the semiconductor substrate. The wiring layer includes a structure including a reflecting surface that reflects light incident from a side of the semiconductor substrate to the semiconductor substrate. A plurality of the pixels have a periodic structure having one or a plurality of pixels as a minimum unit. The structure does not have regularity in a fractional coverage of the reflecting surface in each pixel with respect to a plurality of pixels included in a unit region wider than the minimum unit.

### TECHNICAL FIELD

The present technology relates to a solid-state imaging element, a method of manufacturing a solid-state imaging element, and an electronic device.

### BACKGROUND ART

So-called rear surface irradiation type complementary metal oxide semiconductor (CMOS) image sensors are configured such that a multilayer wiring layer is stacked on a surface side of a semiconductor substrate, a color filter, an on-chip microlens, and the like are stacked on a rear surface side of the semiconductor substrate, and light from a subject is incident from the rear surface side of the semiconductor substrate, for example, as disclosed in Patent Literature 1.

### CITATION LIST

### Patent Literature

Patent Literature 1: JP 2015-164210A

### DISCLOSURE OF INVENTION

### Technical Problem

In a rear surface irradiation type CMOS image sensor, a photoelectric conversion element such as a photodiode is formed for each pixel on a semiconductor substrate, and photoelectric conversion of a portion or the entirety of incident light from a rear surface side of the semiconductor substrate is performed while the incident light passes through the inside of the photoelectric conversion element of each pixel. A portion of light which has not been subjected to photoelectric conversion while the light is directed toward the surface side from the rear surface side of the semiconductor substrate may escape to a multilayer wiring layer, and another portion of light may be reflected by a metal wiring of the multilayer wiring layer, or the like and then be incident on the photoelectric conversion element again.

The metal wiring formed in the multilayer wiring layer is regularly formed so as to have substantially the same layout in each pixel region, for example, as shown in a schematic cross-sectional structural drawing of Patent Literature 1. For this reason, even when light reflected from the wiring of the multilayer wiring layer is incident on the photoelectric conversion element again, variations in a photoelectric conversion rate with respect to the amount of incident light do not occur between pixels, and a pattern corresponding to the shape of the metal wiring is not reflected in an image. However, structures of multilayer wiring layers also include a structure formed across pixels and a structure in which a different layout is formed in each pixel.

For example, an Al wiring embedded in the vicinity of the surface (a side not facing a semiconductor substrate) of a multilayer wiring layer is a structure playing a role as a reinforcing member for improving surface flatness of the multilayer wiring layer at the time of performing chemical mechanical polishing (CMP) to flatten the surface of the multilayer wiring layer before adhering a supporting substrate to the surface of the multilayer wiring layer. In a manufacturing process, it is difficult to make an Al wiring thinner than other Cu wirings and the like, and it may be difficult to make an Al wiring narrower than a pixel pitch which has becomes significantly miniaturized in recent years. For this reason, the Al wiring may be formed across region sections of pixels or have a different layout in each pixel. In such a case, there is a likelihood that a pattern corresponding to the shape of an Al metal wiring be reflected in an image.

The present technology is contrived in view of the above-described problems, and an object thereof is to reduce the probability of lowering an image quality due to reflected light which is reflected by a structure of a multilayer wiring layer stacked on a surface side of a semiconductor substrate and is incident on a photoelectric conversion element again in a solid-state imaging element such as a rear surface irradiation type CMOS image sensor.

### Solution to Problem

An aspect of the present technology is a solid-state imaging element including: a semiconductor substrate on which a plurality of pixels each including a photoelectric conversion section are disposed in parallel along a planar direction; and a wiring layer which is stacked on a surface on a side opposite to a light incidence surface of the semiconductor substrate. The wiring layer includes a structure including a reflecting surface that reflects light incident from a side of the semiconductor substrate to the semiconductor substrate. A plurality of the pixels have a periodic structure having one or a plurality of pixels as a minimum unit. The structure does not have regularity in a fractional coverage of the reflecting surface of each pixel with respect to a plurality of pixels included in a unit region wider than the minimum unit.

Note that the above-described solid-state imaging element has various applications such as implementation in a state where the solid-state imaging element is built into another apparatus or implementation together with another method. In addition, the present technology can be realized as an imaging system including the above-described solid-state imaging element, a method of manufacturing the above-described apparatus, a control program for causing a manufacturing apparatus to realize functions corresponding to steps of the manufacturing method, a computer-readable recording medium having the control program recorded thereon, and the like.

### Advantageous Effects of Invention

According to the present technology, in a solid-state imaging element such as a rear surface irradiation type CMOS image sensor, it is possible to reduce the probability of lowering an image quality due to incident light which is reflected by a structure of a metal wiring included in a wiring layer stacked on a surface side of a semiconductor substrate, having a photoelectric conversion element formed thereon, and is incident on the photoelectric conversion element again. Note that effects described in the present specification are merely examples and not limited, and there may be additional effects.

### BRIEF DESCRIPTION OF DRAWINGS

FIG. 1 is a cross-sectional view showing a main structure of a solid-state imaging element.

FIG. 2 is a diagram for describing a wiring layout inside a unit region.

FIG. 3 is a diagram describing a multilayer wiring layer in a pixel region and a peripheral circuit region.

FIG. 4 is a diagram describing an example of a method of manufacturing a solid-state imaging element.

FIG. 5 is a diagram describing an example of a method of manufacturing a solid-state imaging element.

FIG. 6 is a diagram describing an example of a method of manufacturing a solid-state imaging element.

FIG. 7 is a diagram describing an example of a method of manufacturing a solid-state imaging element.

FIG. 8 is a diagram describing an example of a method of manufacturing a solid-state imaging element.

FIG. 9 is a diagram describing an example of a method of manufacturing a solid-state imaging element.

FIG. 10 is a diagram describing an example of a method of manufacturing a solid-state imaging element.

FIG. 11 is a diagram describing an example of a method of manufacturing a solid-state imaging element.

FIG. 12 is a diagram describing an example of a method of manufacturing a solid-state imaging element.

FIG. 13 is a block diagram showing a configuration of an imaging device including a solid-state imaging element.

FIG. 14 is a block diagram showing a configuration of a solid-state imaging element.

FIG. 15 is a diagram describing a circuit configuration of a pixel.

FIG. 16 is a diagram showing a configuration of an A/D conversion section.

### MODE(S) FOR CARRYING OUT THE INVENTION

Hereinafter, the present technology will be described in the following order.

(A) First embodiment:
(B) Second embodiment:
(C) Third embodiment:

### (A) First Embodiment

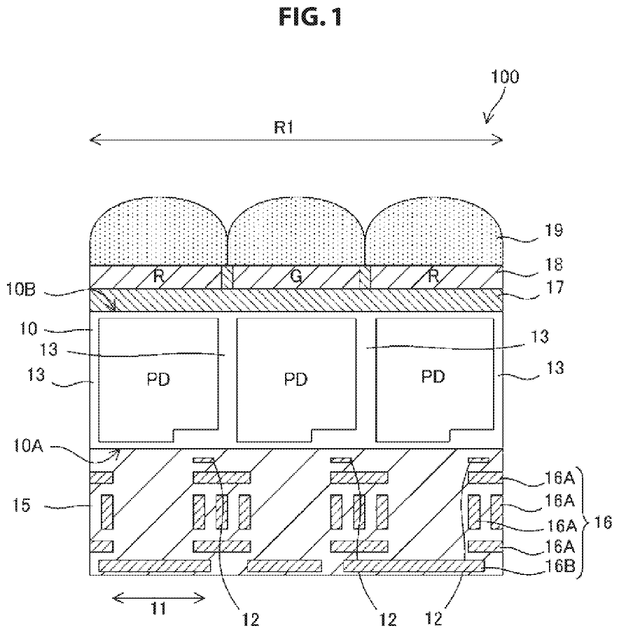

FIG. 1 is a cross-sectional view showing a main structure of a solid-state imaging element 100.

The solid-state imaging element 100, which is a rear surface irradiation type CMOS image sensor, includes a pixel region R1 (a so-called imaging region) in which a plurality of unit pixels 11 are arranged on a semiconductor substrate 10 such as a silicon substrate, and a peripheral circuit region R2 (not shown in FIG. 1) which is disposed in the vicinity of the pixel region R1.

In each of the unit pixels 11 of the semiconductor substrate 10, a photodiode PD as a photoelectric conversion section and pixel transistors (for example, a transfer transistor, a reset transistor, an amplification transistor, and a selection transistor) are provided. The pixel transistors are formed on the side of a surface 10A of the semiconductor substrate 10. FIG. 1 schematically shows the presence of a pixel transistor by showing a gate electrode 12. The photodiode PD is formed at a position facing a rear surface 10B of the semiconductor substrate 10. The photodiodes PD are separated by an element isolation region 13 of an impurity diffusion layer.

A flattening film 17 is formed on the rear surface 10B as a light incidence surface facing the photodiodes PD of the semiconductor substrate 10, and color filters 18 constituted by a plurality of color filters formed so as to respectively correspond to the photodiodes PD are formed on the flattening film 17. The color filters 18 can be configured such that, for example, three primary colors of red (R), green (G), and blue (B) (B is not shown in FIG. 1) are arranged in a Bayer array. In addition, a color filter of a white pixel may be provided, or a color filter selectively transmitting infrared light may be provided.

A microlens 19 is provided on the color filter 18 on the rear surface side of the semiconductor substrate 10. A plurality of microlenses 19 are formed to have substantially the same shape so as to respectively correspond to the plurality of photodiodes PD arranged in the pixel region R1.

A multilayer wiring layer 16 having a plurality of wirings formed therein is provided on a side of the surface 10A of the semiconductor substrate 10 with an insulating interlayer 15 therebetween. The surface 10A of the semiconductor substrate 10 on which the multilayer wiring layer 16 is formed is a surface on a side opposite to a light incidence surface. For this reason, in the rear surface irradiation type CMOS image sensor, the multilayer wiring layer 16 does not block incident light on the photodiodes PD formed on the semiconductor substrate 10.

The multilayer wiring layer 16 formed in the pixel region R1 includes a first wiring layer 16A and a second wiring layer 16B. In the present embodiment, a surface of the second wiring layer 16B on a side facing the semiconductor substrate 10 constitutes a reflecting surface. The first wiring layer 16A is provided so as to have substantially the same wiring layout within an area of a unit region U1 including one or the plurality of unit pixels 11. The second wiring layer 16B is provided such that regularity does not occur in a wiring layout within an area of a unit region U2 which is wider than the unit region U1.

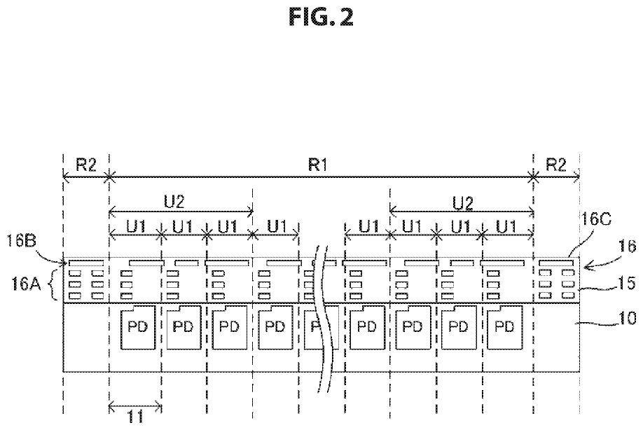

FIG. 2 is a diagram describing the multilayer wiring layer 16 in the pixel region R1 and the peripheral circuit region R2. In the drawing, only the semiconductor substrate 10 and the multilayer wiring layer 16 are shown for convenience of description.

As described above, the solid-state imaging element 100 includes the pixel region R1 and the peripheral circuit region R2 which are set as areas in a planar direction along the surface 10A or the rear surface 10B. The pixel region R1 is a region in which the plurality of unit pixels 11 are formed. The peripheral circuit region R2 is a region in which various circuits for processing signals to be output from a pixel are formed.

The pixel region R1 has a periodic structure in which the unit region U1 repeatedly appears. The unit region U1 is a range including one or the plurality of unit pixels 11. For example, as shown in FIG. 2, the unit pixel 11 itself may be set to be the unit region U1, or a plurality of pixels sharing one floating diffusion may be set to be the unit region U1. A wiring layout of the first wiring layer 16A formed within a certain unit region U1 is substantially the same as a wiring layout of the first wiring layer 16A formed within another unit region U1.

In addition, the pixel region R1 is configured to include one or a plurality of unit regions U2. The unit region U2 is a range which is wider than the unit region U1 and includes a larger number of unit pixels 11 than the number of unit pixels 11 included in the unit region U1. The unit region U2 may be set to be, for example, the entirety of the pixel region R1 or the entirety of the pixel region R1 within an angle of view. The unit region U2 does not have regularity with respect to a fractional coverage of the second wiring layer 16B in each pixel within at least a range of the unit region U2. The fractional coverage refers to a fraction within an area of a pixel section occupied by the area of the second wiring layer 16B.

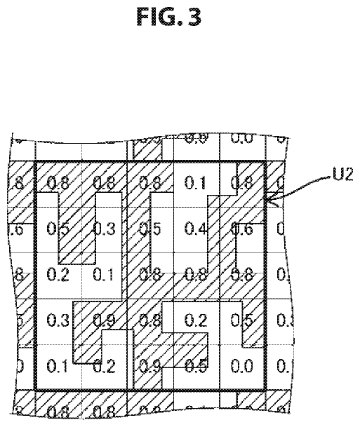

FIG. 3 is a diagram describing a wiring layout within the unit region U2. In the example shown in the drawing, the unit region U2 is a structure in which five unit pixels 11 in the row direction and five unit pixels 11 in the column direction are arranged in a matrix shape. A hatched portion shown in the drawing is a wiring layout of the second wiring layer 16B, and a numerical value shown in each pixel frame is a fractional coverage as a fraction within a section of each of the unit pixels 11 occupied by the second wiring layer 16B.

An array of the fractional coverages in the row direction is “0.8, 0.8, 0.8, 0.1, 0.8”, “0.5, 0.3, 0.5, 0.4, 0.6”, “0.2, 0.1, 0.8, 0.8, 0.8”, “0.3, 0.9, 0.8, 0.2, 0.5”, and “0.1, 0.2, 0.9, 0.5, 0.0” in this order from the top, and no rows have the same array of fractional coverages. Note that “the same array of fractional coverages” may include an array in which an array pattern of specific fractional coverages is shifted in an array direction or an array in which an array direction is reversed.

In addition, an array of fractional coverages in the column direction is “0.8, 0.5, 0.2, 0.3, 0.1”, “0.8, 0.3, 0.1, 0.9, 0.2”, “0.8, 0.5, 0.8, 0.8, 0.9”, “0.1, 0.4, 0.8, 0.2, 0.5”, and “0.8, 0.6, 0.8, 0.5, 0.0” in this order from the left, and neither column has the same array of fractional coverages.

In this manner, it is possible to prevent regularity from occurring in a wiring layout within the range of the unit region U2 by adopting a configuration in which an array pattern of fractional coverages of a plurality of pixels constituting a certain row and an array pattern of fractional coverages of a plurality of pixels constituting another row do not duplicate each other, and an array pattern of fractional coverages of a plurality of pixels constituting a certain column and an array pattern of fractional coverages of a plurality of pixels constituting another column do not duplicate each other within the unit region U2.

In addition, a wiring constituting the second wiring layer 16B may be randomly formed so as to neglect a layout of the unit pixels 11. That is, it is possible to adopt a wiring shape in which a shape covering a portion of the region of the unit pixel 11, a shape covering a plurality of unit pixels 11, and a shape covering the entire region of the unit pixels 11 are variously combined with each other, independently of the division of the unit pixel 11.

In the multilayer wiring layer 16 formed in this manner, the second wiring layer 16B is formed in the above-described form on a surface 16C of the multilayer wiring layer, and thus an area with improved flatness is irregularly formed. Further, in a case in which light, which is reflected light of light incident on the solid-state imaging element 100 and is reflected by the second wiring layer 16B, is incident on the photodiode PD again, it is difficult for fluctuation appearing in an image, which appears on the basis of an image signal output by the solid-state imaging element due to an influence of a reflected light component to be seen as a pattern by the human eyes due to its irregularity.

Naturally, such influence of reflection also occurs at a boundary between layers having different refractive indexes, in addition to the wiring of the multilayer wiring layer 16. Specifically, a multilayer wiring layer has constituent elements such as a gate, a gate insulating film, an insulating interlayer, and the like of a transistor in addition to wiring, and these constituent elements are formed using polysilicon, a silicon oxide film, a silicon nitride film, a silicon carbide film, and the like. Similarly, regarding a boundary between layers of constituent elements, as in the unit region U2, it is possible to adopt the same shape as that of the second wiring layer 16B in a case in which fractional coverages of the second wiring layer 16B in each unit pixel 11 do not have regularity within a range of at least the unit region U2, the range being wider than that of the unit region U1 and including a larger number of unit pixels 11 than the number of unit pixels 11 included in the unit region U1.

In addition, a configuration in which an array pattern of fractional coverages of a plurality of unit pixels 11 constituting a certain row and an array pattern of fractional coverages of a plurality of unit pixels 11 constituting another row do not duplicate each other and an array pattern of fractional coverages of a plurality of unit pixels 11 constituting a certain column and an array pattern of fractional coverages of a plurality of unit pixels 11 constituting another column do not duplicate each other may be adopted for each color of the unit pixel 11. In this case, since a color having lower photoelectric conversion efficiency (a color having a longer wavelength) is more likely to generate reflected light when light incident on the multilayer wiring layer 16 escapes, it is preferable to adopt a configuration in which fractional coverages do not have regularity particularly with respect to the unit pixels 11 of colors having relatively low photoelectric conversion efficiency in the photodiode PD. Specifically, since photoelectric conversion efficiency of the photodiode PD increases in the order of blue light, green light, red light, and infrared light, it is effective to adopt a configuration in which fractional coverages of the second wiring layer 16B do not have regularity particularly with respect to the unit pixels 11 of infrared light and red light.

The multilayer wiring layer 16 in the peripheral circuit region R2 has a wiring layout different from that of the pixel region R1, and particularly, a wiring density of the first wiring layer 16A is higher in the peripheral circuit region R2 than in the pixel region R1. In addition, the second wiring layer 16B in the peripheral circuit region R2 may have regularity in a wiring layout.

The first wiring layer 16A is constituted by, for example, copper (Cu) wiring. The second wiring layer 16B is constituted by, for example, aluminum (Al) wiring. Naturally, materials of the first wiring layer 16A and the second wiring layer 16B are not particularly limited, and it is possible to adopt any metal which is likely to be used for wiring in a solid-state imaging element, such as Al, Cu, tantalum (Ta), or tungsten (W).

### (B) Second Embodiment

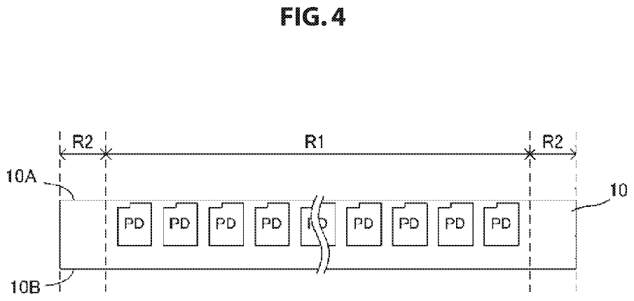

FIGS. 4 to 12 are diagrams describing an example of a method of manufacturing a solid-state imaging element 100. These drawings schematically show a main cross-sectional structure formed in each step of the method of manufacturing the solid-state imaging element 100.

First, as shown in FIG. 4, constituent elements (an element isolation, photodiodes PD, a source region and a drain region of a pixel transistor, and the like) of a plurality of unit pixels 11 are formed in a two-dimensional array having a two-dimensional matrix shape, for example, by ion implantation from the side of a surface 10A of a semiconductor substrate 10 in a region where a pixel region R1 of the semiconductor substrate 10 is to be formed. Note that FIG. 4 illustrates only the photodiode PD. A gate electrode is stacked on each of the unit pixels 11 with a gate insulating film therebetween. Note that the photodiode PD on each of the unit pixels 11 may be formed to have a thickness ranging from the surface 10A of the semiconductor substrate 10 to a fixed depth in a thickness direction of the substrate, and the semiconductor substrate 10 may be polished and ground by a fixed thickness from a rear surface 10B side of the semiconductor substrate 10 to the vicinity of the rear surface side of the photodiode PD in a subsequent step.

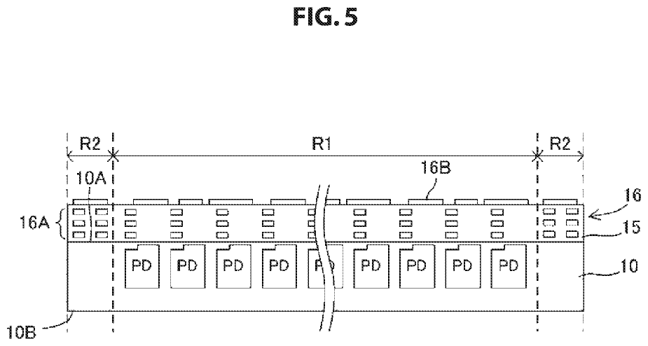

Next, as shown in FIG. 5, a multilayer wiring layer 16 having a plurality of layers of wirings disposed therein is stacked on the surface 10A through an insulating interlayer 15. The multilayer wiring layer 16 includes a first wiring layer 16A constituted by a plurality of wiring layers except for a wiring layer farthest from the surface 10A, and a second wiring layer 16B constituted by the wiring layer farthest from the surface 10A. The wirings of the first wiring layer 16A are constituted by Cu wirings formed by, for example, a Damascene method, and the wirings of the second wiring layer 16B are constituted by Al wirings formed by, for example, an etching method.

The second wiring layer 16B in a peripheral circuit region R2 is used as a PAD metal for outputting a signal to the outside of a chip. The second wiring layer 16B in the pixel region R1 is set not to be connected to other wirings or is set to be connected to only wirings of a power source and a ground. In the wirings of the second wiring layer 16B, a wiring density in the pixel region R1 is substantially the same as a wiring density outside an angle of view (the peripheral circuit region R2). The wirings of the second wiring layer 16B are formed in a layout having no regularity in the above-described unit region U2 within a range (in a case of Al wirings, for example, Line/Space=0.8 μm/2.0 μm or the like) of a miniaturization limit of a wiring in both the pixel region R1 and the peripheral circuit region R2.

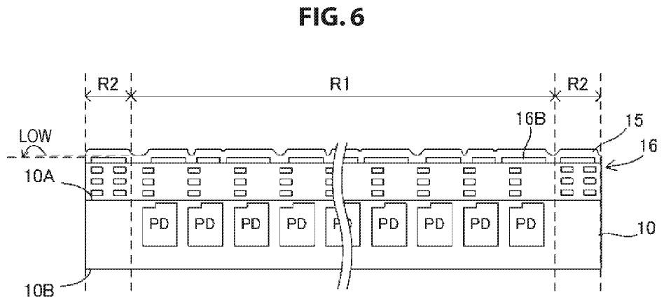

After the second wiring layer 16B is formed, the insulating interlayer 15 such as a SiO2 film is stacked on the second wiring layer 16B as shown in FIG. 6, as a step of forming the multilayer wiring layer 16. The insulating interlayer 15 is stacked until the entire insulating interlayer becomes thicker than the second wiring layer 16B. That is, the insulating interlayer 15 stacked on the second wiring layer 16B is stacked in the form of a surface having irregularities corresponding to irregularities of the second wiring layer 16B, but is stacked such that the lowest point of the deepest recess becomes higher than the highest point of the second wiring layer 16B.

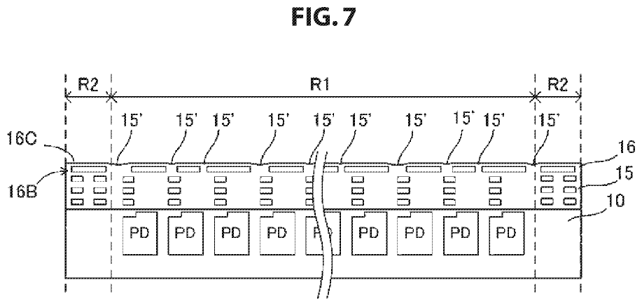

A convex portion of the insulating interlayer 15 stacked in this manner is flattened through CMP as shown in FIG. 7, and the multilayer wiring layer 16 is formed to have a substantially flat surface. Although a portion of the multilayer wiring layer 16 which is formed to rise and include mainly the second wiring layer 16B is strongly polished and ground through CMP, a recessed portion not including the second wiring layer 16B is also weakly polished and ground. Therefore, when CMP is performed to such a degree that the insulating interlayer 15 covering the second wiring layer 16B is left to have a substantially fixed thickness, a concave portion 15′ in which the insulating interlayer 15 covering a portion having no second wiring layer 16B is slightly recessed, rather than the insulating interlayer 15 covering a portion having the second wiring layer 16B, is formed. When a supporting substrate 200 to be described later is bonded to a surface 16C of the multilayer wiring layer 16, the concave portion 15′ has insufficient adhesive strength or remains a cavity without being adhered. However, in the solid-state imaging element 100 according to the present embodiment, a formation density of the second wiring layer 16B in the pixel region R1 is increased, and thus the insulating interlayer 15 covering a portion having the second wiring layer 16B is provided over substantially the entire region of the pixel region R1 at a fixed density or higher. That is, a substantially flat surface is formed over the entire region of the multilayer wiring layer 16.

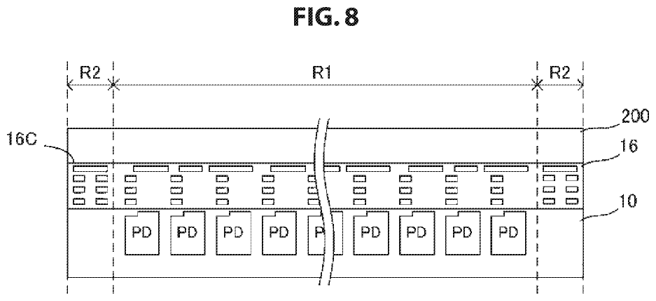

The supporting substrate 200 is bonded to the substantially flat surface of the multilayer wiring layer 16 formed in this manner, as shown in FIG. 8. For example, a silicon substrate is used for the supporting substrate 200. Note that, for convenience of illustration, FIG. 8 does not show the above-described concave portion 15′, and a description of a detailed shape of the surface 16C of the multilayer wiring layer 16 is omitted.

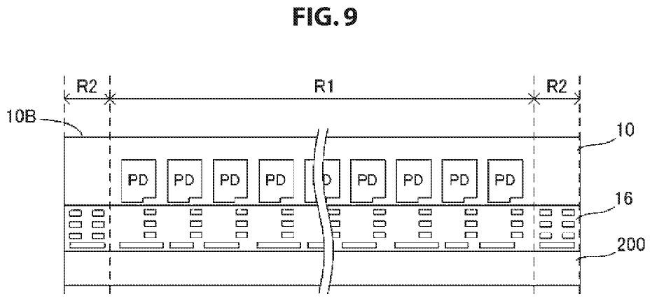

Next, as shown in FIG. 9, the semiconductor substrate 10 having the supporting substrate 200 bonded thereto is turned upside down, and the rear surface 10B of the semiconductor substrate 10 is set to be an upper surface.

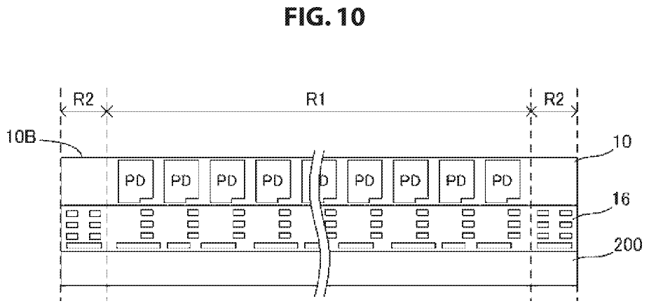

Next, as shown in FIG. 10, removal processing is performed from the rear surface 10B of the semiconductor substrate 10 to the vicinity of the rear surface of the photodiode PD through polishing and grinding. Finally, the rear surface 10B of the semiconductor substrate 10 is processed smooth and flat through CMP. Note that it is also possible to perform processing at the final stage through etching.

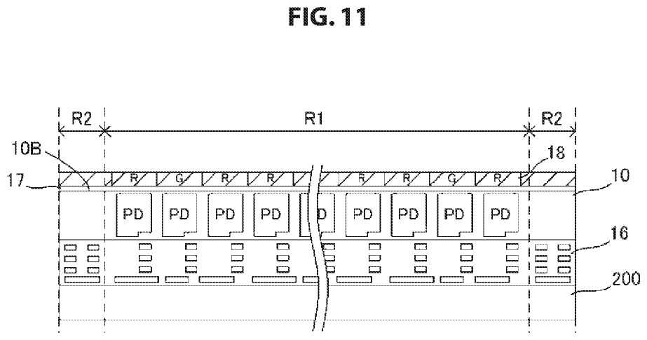

Next, as shown in FIG. 11, a transparent flattening film 17 and color filter 18 are formed on the rear surface 10B of the semiconductor substrate 10. The flattening film 17 is formed, for example, by forming a thermoplastic resin by a spin coating method and then performing heat curing treatment. The color filter 18 of, for example, a Bayer array is formed on the flattening film 17 as a primary color filter of green, red, and blue. The color filter 18 is formed corresponding to each of the unit pixels 11, and is constituted by three color filters of, for example, a red (R) filter, a green (G) filter, and a blue (B) filter. The color filter 18 is not limited to the three primary colors of light, and it is also possible to use a complementary color filter or use a white color filter in combination. A flattening film may further be provided on the upper surface of the color filter 18 as necessary.

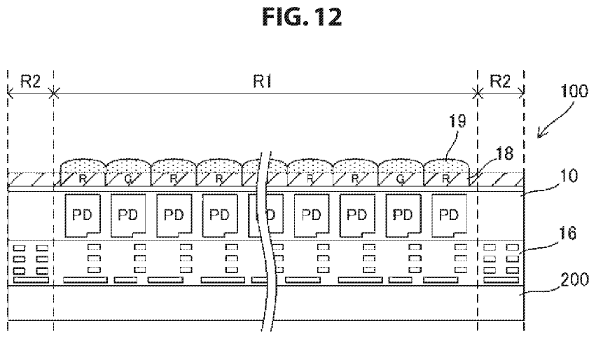

Next, as shown in FIG. 12, a microlens 19 is formed on the color filter 18. The microlens 19 is formed by, for example, forming a positive type photoresist film on the color filter 18 and then processing the photoresist film.

It is possible to manufacture the above-described solid-state imaging element 100 by the above-described manufacturing method.

### (C) Third Embodiment

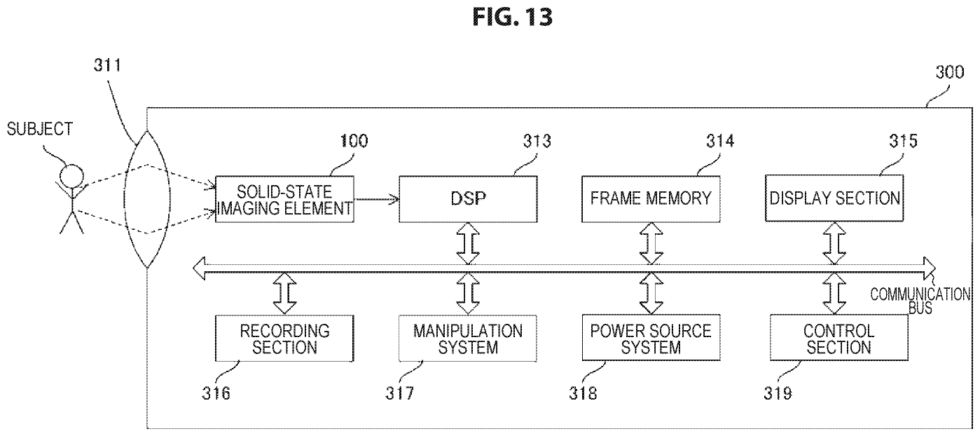

FIG. 13 is a block diagram showing a configuration of an imaging device 300 including a solid-state imaging element 100. The imaging device 300 shown in the drawing is an example of an electronic device.

Note that, in the present specification, the imaging device refers to all electronic device using a solid-state imaging element for an image capture section (a photoelectric conversion section), such as imaging devices such as digital still cameras and digital video cameras, and mobile terminal devices such as mobile phones having imaging functions. As a matter of course, examples of the electronic device using a solid-state imaging element for an image capture section include also copying machines using a solid-state imaging element for an image reading section. Further, in order to be mounted on the electronic devices described above, the imaging device may be modularized including a solid-state imaging element.

In FIG. 13, the imaging device 300 includes an optical system 311 including a lens group, a solid-state imaging element 100, a digital signal processor (DSP) 313 as a signal processing circuit that processes output signals of the solid-state imaging element 100, a frame memory 314, a display section 315, a recording section 316, a manipulation system 317, a power source system 318, and a control section 319.

The DSP 313, the frame memory 314, the display section 315, the recording section 316, the manipulation system 317, the power source system 318, and the control section 319 are connected together via a communication bus so as to be able to transmit and receive data and signals with each other.

The optical system 311 captures incident light (image light) from a subject, and forms an image on an imaging surface of a solid-state imaging element 100. The solid-state imaging element 100 generates, on a pixel basis, an electrical signal in accordance with the amount of received incident light that is formed as an image on the imaging surface by the optical system 311, and outputs the electrical signal as a pixel signal. The pixel signal is inputted to the DSP 313, and the image data generated by performing various pieces of image processing as appropriate is stored in the frame memory 314, recorded on a recording medium of the recording section 316, and outputted to the display section 315.

The display section 315 includes a panel-type display device such as a liquid crystal display device or an organic electro-luminescence (EL) display device, and displays moving images and still images captured by the solid-state imaging element 100 and other information. The recording section 316 records moving images and still images captured by the solid-state imaging element 100 on a recording medium such as a digital versatile disk (DVD), a hard disk (HD), or a semiconductor memory.

The manipulation system 317 accepts various manipulations from the user, and transmits manipulation orders in accordance with the user's manipulations to the sections 313, 314, 315, 316, 318, and 319 via the communication bus. The power source system 318 generates various power source voltages serving as driving power sources, and supplies the power source voltages to supply destinations (the sections 312, 313, 314, 315, 316, 317, and 319), as appropriate.

The control section 319 includes a CPU that performs arithmetic processing, a ROM that stores a control program of the imaging device 300, a RAM functioning as a work area of the CPU, etc. Using the RAM as a work area, the control section 319 controls the sections 313, 314, 315, 316, 317, and 318 via the communication bus by the CPU executing the control program stored in the ROM. Further, the control section 319 controls a not-shown timing generator to generate various timing signals, and performs control for supplying the timing signals to the sections.

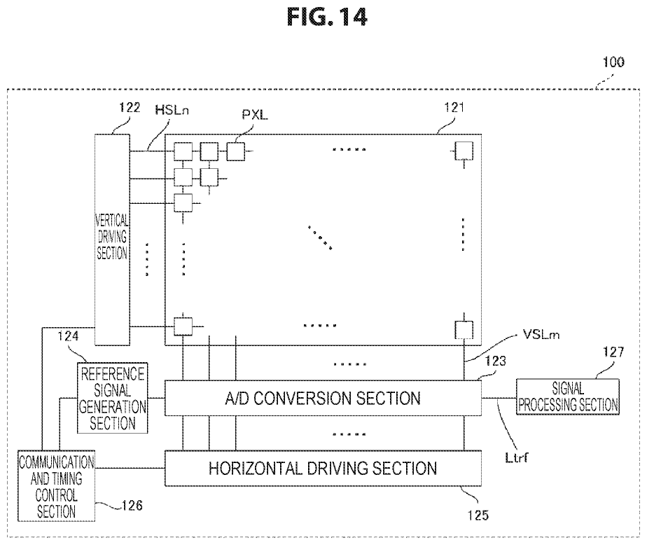

FIG. 14 is a block diagram showing a configuration of the solid-state imaging element 100. Note that, in the present embodiment, a description is given by taking a CMOS image sensor which is a type of X-Y address type solid-state imaging device as an example of the solid-state imaging device, but of course, a CCD image sensor may be adopted. Hereinafter, a specific example of a solid-state imaging device as a CMOS image sensor will be described with reference to FIG. 14.

In FIG. 14, the solid-state imaging element 100 includes a pixel section 121, a vertical driving section 122, analog/digital conversion section 123 (A/D conversion section 123), a reference signal generation section 124, a horizontal driving section 125, a communication and timing control section 126, and a signal processing section 127.

In the pixel section 121, a plurality of pixels PXL each including a photodiode as a photoelectric conversion section are arranged in a two-dimensional matrix form. A color filter array in which the colors of filters are partitioned to correspond to pixels is provided on the light receiving surface side of the pixel section 121. Note that a specific circuit configuration of the pixel PXL is described later.

In the pixel section 121, n pixel driving lines HSLn (n=1, 2, . . . ) and m vertical signal lines VSLm (m=1, 2, . . . ) are wiring. The pixel driving lines HSLn are wired along the right-left direction in the drawing (a pixel arrangement direction of a pixel row/horizontal direction), and are disposed at equal intervals in the up-down direction in the drawing. The vertical signal lines VSLm are wired along the up-down direction in the drawing (a pixel arrangement direction of a pixel column/vertical direction), and are disposed at equal intervals in the right-left direction in the drawing.

An end of the pixel driving line HSLn is connected to an output terminal corresponding to each row of the vertical driving section 122. The vertical signal line VSLm is connected to the pixel PXL of each column, and an end thereof is connected to the A/D conversion section 123. The vertical driving section 122 and the horizontal driving section 125 perform control for sequentially reading out analog signals from the pixels PXL constituting the pixel section 121 under the control of the communication and timing control section 126. Note that specific connection between the pixel driving line HSLn and the vertical signal line VSLm for each of the pixels PXL will be described later together with a description of the pixel PXL.

The communication and timing control section 126 includes a timing generator and a communication interface, for example. The timing generator generates various clock signals on the basis of a clock (a master clock) inputted from the outside. The communication interface receives data that specify operating modes, etc. given from the outside of a solid-state imaging element 100, and outputs data including inside information of the solid-state imaging element 100 to the outside.

On the basis of a master clock, the communication and timing control section 126 generates a clock with the same frequency as the frequency of the master clock, a clock with a frequency obtained by dividing the master clock's frequency by 2, a clock with a lower speed obtained by dividing the master clock's frequency by a larger number, etc., and supplies them to the sections in the device (the vertical driving section 122, the horizontal driving section 125, the A/D conversion section 123, the reference signal generation section 124, the signal processing section 127, etc.).

The vertical driving section 122 includes a shift register, an address decoder, etc., for example. The vertical driving section 122 includes a vertical address setting section for controlling the row address and a row scanning control section for controlling row scanning, on the basis of a signal obtained by decoding a video signal inputted from the outside.

The vertical driving section 122 can perform readout scanning and sweep scanning.

The readout scanning is scanning that sequentially selects unit pixels from which signals are to be read out. The readout scanning is basically performed in a sequential manner on a row basis; however, in a case where thinning-out of pixels is performed by adding or averaging outputs of a plurality of pixels that are in a prescribed positional relationship, the readout scanning is performed in a prescribed order.

The sweep scanning is scanning that is performed on a row or a pixel combination that is to be read out by readout scanning and that causes the unit pixels belonging to the row or the pixel combination to be reset prior to the readout scanning by a time equal to the time of the shutter speed.

The horizontal driving section 125 sequentially select ADC circuits included in the A/D conversion section 123 in synchronization with a clock outputted by the communication and timing control section 126. The A/D conversion section 123 includes ADC circuits provided for the vertical signal lines VSLm (m=1, 2, . . . ); and converts an analog signal outputted from each vertical signal line VSLm to a digital signal, and outputs the digital signal to a horizontal signal line Ltrf in accordance with the control of the corresponding one of the horizontal driving section 125.

The horizontal driving section 125 includes a horizontal address setting section and a horizontal scanning section, for example; and selects an ADC circuit of the corresponding one of the A/D conversion section 123, which circuit corresponds to a readout column in the horizontal direction specified by the horizontal address setting section, and thereby guides a digital signal generated in the selected ADC circuit to the horizontal signal line Ltrf.

Digital signals thus outputted from the A/D conversion section 123 are inputted to the signal processing section 127 via the horizontal signal lines Ltrf. The signal processing section 127 performs processing in which signals outputted from the pixel section 121 via the A/D conversion section 123 are converted to an image signal corresponding to the color arrangement of the color filter array by arithmetic processing.

Further, the signal processing section 127 performs, as necessary, processing in which pixel signals in the horizontal direction and the vertical direction are thinned out by addition, averaging, or the like. An image signal thus generated is outputted to the outside of the solid-state imaging element 100.

The reference signal generation section 124 includes a digital/analog converter (DAC), and generates a reference signal Vramp in synchronization with a counting clock supplied from the communication and timing control section 126. The reference signal Vramp has a saw-tooth-like wave (a ramp waveform) that temporally changes in a staircase form from the initial value supplied from the communication and timing control section 126. The reference signal Vramp is supplied to each of the ADC circuits of the A/D conversion section 123.

The A/D conversion section 123 includes a plurality of ADC circuits. When A/D-converting an analog voltage outputted from each pixel PXL, the ADC circuit uses a comparator to compare the reference signal Vramp and the voltage of the vertical signal line VSLm in a prescribed A/D conversion period (a P-phase period or a D-phase period described later), and uses a counter to count a time period before or after the time at which the magnitude relationship between the reference signal Vramp and the voltage of the vertical signal line VSLm (a pixel voltage) is reversed. Thereby, a digital signal in accordance with the analog pixel voltage can be generated. Note that a specific example of the A/D conversion section 123 is described later.

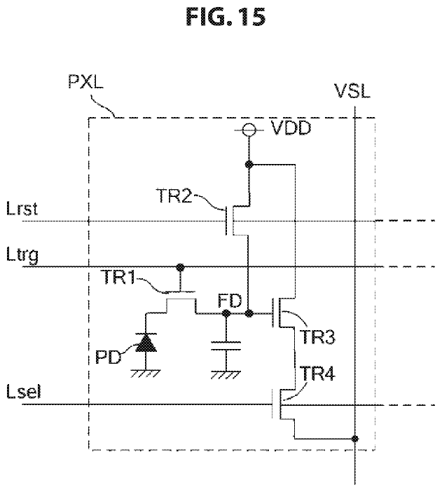

FIG. 15 is a diagram describing a circuit configuration of a pixel. The drawing shows an equivalent circuit of a pixel of a configuration of an ordinary four-transistor system. The pixel shown in the drawing includes a photodiode PD and four transistors (a transfer transistor TR1, a reset transistor TR2, an amplification transistor TR3, and a selection transistor TR4).

The photodiode PD generates a current in accordance with the amount of received light by photoelectric conversion. The anode of the photodiode PD is connected to the ground, and the cathode is connected to the drain of the transfer transistor TR1.

Various control signals are inputted to the pixel PXL from a reset signal generation circuit and various drivers of the vertical driving section 122 via signal lines Ltrg, Lrst, and Lsel.

Signal line Ltrg for transmitting a transfer gate signal is connected to the gate of the transfer transistor TR1. The source of the transfer transistor TR1 is connected to a connection point between the source of the reset transistor TR2 and the gate of the amplification transistor TR3. This connection point is included in a floating diffusion FD that is a capacitance that accumulates signal charge.

The transfer transistor TR1 becomes ON if a transfer signal is inputted to the gate through signal line Ltrg, and transfers signal charge (herein, photoelectrons) accumulated by photoelectric conversion of the photodiode PD to the floating diffusion FD.

Signal line Lrst for transmitting a reset signal is connected to the gate of the reset transistor TR2, and a constant voltage source VDD is connected to the drain. The reset transistor TR2 becomes ON if a reset signal is inputted to the gate through signal line Lrst, and resets the floating diffusion FD to the voltage of the constant voltage source VDD. On the other hand, in a case where a reset signal is not inputted to the gate through signal line Lrst, the reset transistor TR2 is OFF, and forms a prescribed potential barrier between the floating diffusion FD and the constant voltage source VDD.

In the amplification transistor TR3, the gate is connected to the floating diffusion FD, the drain is connected to the constant voltage source VDD, and the source is connected to the drain of the selection transistor TR4.

In the selection transistor TR4, signal line Lsel of a selection signal is connected to the gate, and the source is connected to the vertical signal line VSL. The selection transistor TR4 becomes ON if a control signal (an address signal or a selection signal) is inputted to the gate through signal line Lsel, and is OFF in a case where the control signal is not inputted to the gate through signal line Lsel.

If the selection transistor TR4 becomes ON, the amplification transistor TR3 amplifies the voltage of the floating diffusion FD, and outputs the amplified voltage to the vertical signal line VSL. Voltages outputted from pixels through vertical signal lines VSL are inputted to the A/D conversion section 123.

Note that the circuit configuration of the pixel may employ not only the configuration shown in FIG. 15 but also various known configurations such as a configuration of a three-transistor system and a configuration of another four-transistor system. Examples of the configuration of another four-transistor system include a configuration in which the selection transistor TR4 is placed between the amplification transistor TR3 and the constant voltage source VDD.

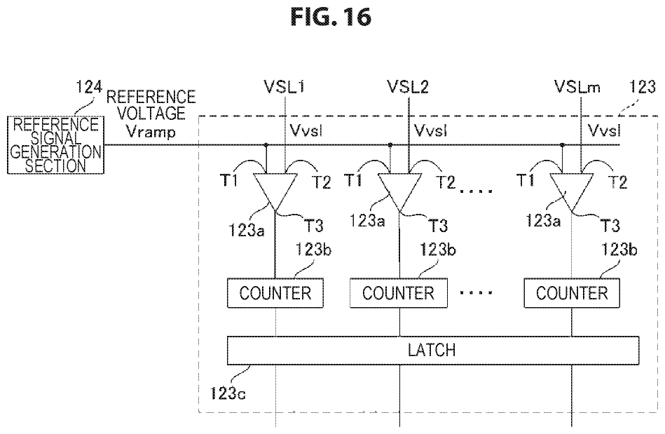

FIG. 16 is a diagram showing a configuration of the A/D conversion section 123. As shown in the drawing, each ADC circuit included in the A/D conversion section 123 includes a comparator 123a and a counter 123b provided for each vertical signal line VSLm, and a latch 123c.

The comparator 123a includes two input terminals T1 and T2 and one output terminal T3. One input terminal T1 receives an input of a reference signal Vramp from the reference signal generation section 124, and the other input terminal T2 receives an input of an analog pixel signal (hereinafter, referred to as a pixel signal Vvsl) which is output from a pixel through the vertical signal line VSL.

The comparator 123a compares the reference signal Vramp and the pixel signal Vvsl with each other. The comparator 123a outputs a high-level or low-level signal in accordance with a magnitude relationship between the reference signal Vramp and the pixel signal Vvsl, and an output of the output terminal T3 is reversed between a high level and a low level when the magnitude relationship between the reference signal Vramp and the pixel signal Vvsl is switched.

The counter 123b is supplied with a clock from the communication and timing control section 126, and uses the clock to count the time from the start to the end of A/D conversion. The timings of the start and the end of A/D conversion are specified on the basis of a control signal outputted by the communication and timing control section 126 (for example, the presence or absence of input of a clock signal CLK, or the like) and an output reversal of the comparator 123a.

In addition, the counter 123b performs A/D conversion of a pixel signal through so-called correlated double sampling (CDS). Specifically, the counter 123b performs down-counting while an analog signal equivalent to a reset component is output from the vertical signal line VSLm under the control of the communication and timing control section 126. In addition, a counting value obtained by the down-counting is set to be an initial value, and up-counting is performed while an analog signal equivalent to a pixel signal is output from the vertical signal line VSLm.

The counting value generated in this manner is set to be a digital value equivalent to a difference between a signal component and the reset component. That is, the counting value serves as a value obtained by calibrating a digital value, equivalent to an analog pixel signal which is input to the A/D conversion section 123 from the pixel through the vertical signal line VSLm, by the reset component.

The digital values generated by the counter 123b are stored in the latch 123c, are sequentially output from the latch 123c under the control of the horizontal scanning section, and are output to the signal processing section 127 through the horizontal signal line Ltrf.

Note that the present technology is not limited to the embodiments described above, and includes also configurations in which configurations disclosed in each of the embodiments described above are substituted with each other or combinations are changed, configurations in which known technology and configurations disclosed in each of the embodiments described above are substituted with each other or combinations are changed, etc. Further, the technical scope of the present technology is not limited to the embodiments described above, and includes also the subject matters described in the claims and the equivalents thereof.

Additionally, the present technology may also be configured as below.

(1)

A solid-state imaging element including:

a semiconductor substrate on which a plurality of pixels each including a photoelectric conversion section are disposed in parallel along a planar direction; and

a wiring layer which is stacked on a surface on a side opposite to a light incidence surface of the semiconductor substrate,

in which the wiring layer includes a structure including a reflecting surface that reflects light incident from a side of the semiconductor substrate to the semiconductor substrate,

a plurality of the pixels have a periodic structure having one or a plurality of pixels as a minimum unit, and

the structure does not have regularity in a fractional coverage of the reflecting surface of each pixel with respect to a plurality of pixels included in a unit region wider than the minimum unit.

(2)

The solid-state imaging element according to (1),

in which the plurality of pixels are two-dimensionally arranged in a matrix, and

an array pattern of the fractional coverages of a plurality of pixels constituting a certain row and an array pattern of the fractional coverages of a plurality of pixels constituting another row do not duplicate each other and an array pattern of the fractional coverages of a plurality of pixels constituting a certain column and an array pattern of the fractional coverages of a plurality of pixels constituting another column do not duplicate each other within the unit region.

(3)

The solid-state imaging element according to (1) or (2), further including:

a color filter which is stacked on the light incidence surface of the semiconductor substrate,

in which a plurality of the pixels have a periodic structure in which one or a plurality of pixels formed corresponding to a color filter of a specific color are set to be a minimum unit, and

the structure does not have regularity in a fractional coverage of the reflecting surface in each pixel with respect to a plurality of pixels included in a unit region wider than the minimum unit.

(4)

The solid-state imaging element according to (1) or (2),

in which a plurality of the pixels have a periodic structure in which one or a plurality of pixels formed corresponding to a color filter of red light or infrared light are set to be a minimum unit, and

the structure does not have regularity in a fractional coverage of the reflecting surface in each pixel with respect to a plurality of pixels included in a unit region wider than the minimum unit.

(5)

A method of manufacturing a solid-state imaging element, the method including:

a step of disposing a plurality of pixels each including a photoelectric conversion section on a semiconductor substrate in parallel along a planar direction; and

a step of stacking a wiring layer on a surface on a side opposite to a light incidence surface of the semiconductor substrate,

in which the wiring layer includes a structure including a reflecting surface that reflects light incident from a side of the semiconductor substrate to the semiconductor substrate,

a plurality of the pixels have a periodic structure having one or a plurality of pixels as a minimum unit, and

the structure does not have regularity in a fractional coverage of the reflecting surface of each pixel with respect to a plurality of pixels included in a unit region wider than the minimum unit.

(6)

An electronic device including:

a solid-state imaging element;

a recording section in which image data generated on the basis of an image signal output by the solid-state imaging element is recorded; and

a display section which displays an image based on the image signal,

in which the solid-state imaging element includes a semiconductor substrate on which a plurality of pixels each including a photoelectric conversion section are disposed in parallel along a planar direction, and a wiring layer which is stacked on a surface on a side opposite to a light incidence surface of the semiconductor substrate,

the wiring layer includes a structure including a reflecting surface that reflects light incident from a side of the semiconductor substrate to the semiconductor substrate,

a plurality of the pixels have a periodic structure having one or a plurality of pixels as a minimum unit, and

the structure does not have regularity in a fractional coverage of the reflecting surface of each pixel with respect to a plurality of pixels included in a unit region wider than the minimum unit.

### REFERENCE SIGNS LIST

10 semiconductor substrate
10A surface
10B rear surface
11 unit pixel
11A surface
12 gate electrode
13 element isolation region
15 insulating interlayer
16 multilayer wiring layer
16A first wiring layer
16B second wiring layer
17 flattening film
18 color filter
19 microlens
100 solid-state imaging element
121 pixel section
122 vertical driving section
123 analog/digital conversion section (A/D conversion section)
123a comparator
123b counter
123c latch
124 reference signal generation section
125 horizontal driving section
126 timing control section
127 signal processing section
300 imaging device
311 optical system
312 DSP
314 frame memory
315 display section
316 recording section
317 manipulation system
318 power source system
319 control section
FD floating diffusion
PD photodiode
PXL pixel
R1 pixel region
R2 peripheral circuit region
TR1 transfer transistor TR1
TR2 reset transistor
TR3 amplification transistor
TR4 selection transistor
U1 unit region
U2 unit region

1. A solid-state imaging element comprising:
a semiconductor substrate on which a plurality of pixels each including a photoelectric conversion section are disposed in parallel along a planar direction; and
a wiring layer which is stacked on a surface on a side opposite to a light incidence surface of the semiconductor substrate,
wherein the wiring layer includes a structure including a reflecting surface that reflects light incident from a side of the semiconductor substrate to the semiconductor substrate,
a plurality of the pixels have a periodic structure having one or a plurality of pixels as a minimum unit, and
the structure does not have regularity in a fractional coverage of the reflecting surface of each pixel with respect to a plurality of pixels included in a unit region wider than the minimum unit.

2. The solid-state imaging element according to claim 1,
wherein the plurality of pixels are two-dimensionally arranged in a matrix, and
an array pattern of the fractional coverages of a plurality of pixels constituting a certain row and an array pattern of the fractional coverages of a plurality of pixels constituting another row do not duplicate each other and an array pattern of the fractional coverages of a plurality of pixels constituting a certain column and an array pattern of the fractional coverages of a plurality of pixels constituting another column do not duplicate each other within the unit region.

3. The solid-state imaging element according to claim 1, further comprising:
a color filter which is stacked on the light incidence surface of the semiconductor substrate,
wherein a plurality of the pixels have a periodic structure in which one or a plurality of pixels formed corresponding to a color filter of a specific color are set to be a minimum unit, and
the structure does not have regularity in a fractional coverage of the reflecting surface in each pixel with respect to a plurality of pixels included in a unit region wider than the minimum unit.

4. The solid-state imaging element according to claim 1,
wherein a plurality of the pixels have a periodic structure in which one or a plurality of pixels formed corresponding to a color filter of red light or infrared light are set to be a minimum unit, and
the structure does not have regularity in a fractional coverage of the reflecting surface in each pixel with respect to a plurality of pixels included in a unit region wider than the minimum unit.

5. A method of manufacturing a solid-state imaging element, the method comprising:
a step of disposing a plurality of pixels each including a photoelectric conversion section on a semiconductor substrate in parallel along a planar direction; and
a step of stacking a wiring layer on a surface on a side opposite to a light incidence surface of the semiconductor substrate,
wherein the wiring layer includes a structure including a reflecting surface that reflects light incident from a side of the semiconductor substrate to the semiconductor substrate,
a plurality of the pixels have a periodic structure having one or a plurality of pixels as a minimum unit, and
the structure does not have regularity in a fractional coverage of the reflecting surface of each pixel with respect to a plurality of pixels included in a unit region wider than the minimum unit.

6. An electronic device comprising:
a solid-state imaging element;
a recording section in which image data generated on a basis of an image signal output by the solid-state imaging element is recorded; and
a display section which displays an image based on the image signal,
wherein the solid-state imaging element includes a semiconductor substrate on which a plurality of pixels each including a photoelectric conversion section are disposed in parallel along a planar direction, and a wiring layer which is stacked on a surface on a side opposite to a light incidence surface of the semiconductor substrate,
the wiring layer includes a structure including a reflecting surface that reflects light incident from a side of the semiconductor substrate to the semiconductor substrate,
a plurality of the pixels have a periodic structure having one or a plurality of pixels as a minimum unit, and
the structure does not have regularity in a fractional coverage of the reflecting surface of each pixel with respect to a plurality of pixels included in a unit region wider than the minimum unit.
